(19) United States
(12) Patent Application Publication
(10) Pub. No.: US 2017/0040158 A1
(43) Pub. Date: Feb. 9, 2017

(54) LOW TEMPERATURE ALD ON SEMICONDUCTOR AND METALLIC SURFACES

(71) Applicants: Applied Materials, Inc., Santa Clara, CA (US); The Regents of the University of California, Oakland, CA (US)

(72) Inventors: Jessica S. KACHIAN, Sunnyvale, CA (US); Naomi YOSHIDA, Sunnyvale, CA (US); Mei CHANG, Saratoga, CA (US); Andrew C. KUMMEL, San Diego, CA (US); Mary EDMONDS, San Diego, CA (US)

(21) Appl. No.: 15/230,197

(22) Filed: Aug. 5, 2016

Related U.S. Application Data
(60) Provisional application No. 62/201,688, filed on Aug. 6, 2015.

(51) Int. Cl. H01L 21/02

(52) U.S. Cl. CPC H01L 21/0228; H01L 21/0217; H01L 21/02211

(57) ABSTRACT

The present disclosure provides for semiconductor fabrication processes that include atomic layer depositions. Embodiments described herein provide for formation of a diffusion barrier or gate dielectric layer in preparation for subsequent ALD on semiconductor surfaces. More specifically, embodiments of the present disclosure provide for the formation of fin field effect transistor (FinFET) and metal oxide semiconductor field effect transistor (MOSFET) devices utilizing improved ALD processes.

### CROSS-REFERENCE TO RELATED APPLICATIONS

This application claims benefit of U.S. provisional patent application Ser. No. 62/201,688, filed Aug. 6, 2015, the entirety of which is herein incorporated by reference.

### BACKGROUND

Field

Embodiments of the present disclosure generally relate to a semiconductor fabrication processes. More specifically, embodiments described herein provide for low temperature atomic layer deposition (ALD) on semiconductor and metallic surfaces.

Description of the Related Art

Atomic layer deposition (ALD) is a thin film deposition method in which a film is grown on a substrate by exposing its surface to alternate gaseous species (typically referred to as precursors). In contrast to chemical vapor deposition, the precursors are not present simultaneously in the reactor, but are introduced into the reaction chamber as a series of sequential, non-overlapping pulses. ALD processes are capable of producing very thin, conformal films with control of the thickness and composition of the films possible at the atomic level.

Current ALD processes often produce films having chemical vapor deposition (CVD) like properties, such as non-self-limiting film growth characteristics. In order to compensate for current ALD process inadequacies, high temperatures, increased reaction pulse times, large precursor pulse pressures, and high reactor chamber temperatures are utilized. However, utilization of the correcting process variables often result in undesirable material properties of the films grown according to these methods. Moreover, the current ALD processes are time consuming which results in reduced throughput.

Accordingly, what is needed in the art are improved ALD processes.

### SUMMARY

In one embodiment, an atomic layer deposition method is provided. The method includes heating a substrate in a reaction chamber to a temperature less than about 300° C., introducing a first precursor pulse comprising N₂H₄ into the reaction chamber, and introducing a second precursor pulse comprising Si₂Cl₆ into the reaction chamber. The first precursor pulse and the second precursor pulse are performed at the temperature less than about 300° C.

In another embodiment, an atomic layer deposition method is provided. The method includes heating a substrate in a reaction chamber to a temperature of about 275° C., introducing a first precursor pulse comprising N₂H₄ at a first dosage into the reaction chamber, and introducing a second precursor pulse comprising SI₂Cl₆ at a second dosage less than the first dosage into the reaction chamber. The first precursor pulse and the second precursor pulse are performed at the temperature less than about 275° C.

In yet another embodiment, an atomic layer deposition method is provided. The method includes heating a substrate in a reaction chamber to a temperature less than about 300° C., introducing a first precursor pulse comprising N₂H₄ at a first dosage of 315 MegaLangmuir into the reaction chamber, and introducing a second precursor pulse comprising Si₂Cl₆ at a second dosage of 21 MegaLangmuir into the reaction chamber. A third precursor pulse comprising N₂H₄ is introduced into the reaction chamber at a third dosage of 3 MegaLangmuir and a fourth precursor pulse comprising Si₂Cl₆ is introduced into the reaction chamber at a fourth dosage of 3 MegaLangmuir. The introducing a third precursor pulse and the introducing a fourth precursor pulse are sequentially repeated

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates x-ray photon spectroscopy (XPS) data for ALD deposited materials on a substrate according to embodiments described herein.

To facilitate understanding, identical reference numerals have been used, where possible, to designate identical elements that are common to the FIGURES. It is contemplated that elements and features of one embodiment may be beneficially incorporated in other embodiments without further recitation.

### DETAILED DESCRIPTION

The present disclosure provides for semiconductor fabrication processes that include atomic layer depositions. Embodiments described herein provide for formation of a diffusion barrier or gate dielectric layer in preparation for subsequent ALD on semiconductor surfaces. More specifically, embodiments of the present disclosure provide for the formation of fin field effect transistor (FinFET) and metal oxide semiconductor field effect transistor (MOSFET) devices utilizing improved ALD processes.

Embodiments provide for ALD of a Si—Nₓ monolayer or multilayer growth on indium gallium arsenide (InGaAs), indium gallium antiminide (InGaSb), indium gallium nitride (InGaN), SiGe, Ge, Si, and other semiconductor substrates of varying alloy compositions, as well as metallic substrates. In one embodiment, the substrate surface is functionalized by —NHₓ termination by dosing high pressure pulses of N₂H₄ at a low ALD temperature below about 300° C., e.g. 275° C. Si₂Cl₆ is then dosed at the low temperature, e.g., 275° C., to produce a Si—Nₓ terminating layer on the semiconductor surface through the production of an HCl(gaseous) byproduct. The cyclic dosing process can be repeated to produce the desired thickness of the deposited Si—Nₓ overlayer.

The silicon nitride ALD is based upon the saturating half-cycle reaction of hydrazine (N₂H₄) with the substrate semiconductor or metallic surface sites through a surface termination with —N—Hₓ groups at a low substrate temperature. Once the surface is terminated by —N—Hₓ, the second half-cycle reaction is initiated by introducing the chlorosilane precursor in order to produce a saturating —N—Si—Clₓ terminating layer and an HCl(g) desorption byproduct. Chlorosilane precursors include, but are not limited to SiCl₄, Si₂Cl₆, and Si₃Cl₈. Suitable chlorosilane precursors may generally conform to the following formula:

SiₓCl_{y}H_{z}, where y>z.

Embodiments describe herein employ high half cycle pulses for both precursors (e.g. nitrogen containing precursor and silicon containing precursor), which protect the substrate and deposited films from unwanted contamination. A high vacuum base pressure immediately prior to ALD growth is utilized to reduce carbon and oxygen presence during ALD growth to further reduce contamination of the ALD films. In one embodiment, anhydrous hydrazine delivered from a vaporizer which is equipped with a membrane that preferentially allows hydrazine vapor to pass through relative to other materials is implemented to further reduce the potential for contamination. Accordingly, high purity silicon nitride ALD films can be achieved.

The embodiments described herein provide for silicon nitride film formation without utilization of high temperature post annealing. Embodiments described herein also enable uniform or substantially uniform silicon nitride growth across an entire substrate surface. Methods described herein may be advantageously employed in gate oxide deposition applications, diffusion barrier deposition applications, surface functionalization applications, surface passivation applications, and oxide nucleation applications.

As utilized herein, functionalization is creating a surface which is reactive to ALD precursors. Passivation is forming a monolayer or thin control layer which leaves the Fermi level unpinned. Monolayer nucleation is initiation of the ALD process in each unit cell. The silicon nitride ALD process described herein achieves functionalization, passivation, and nucleation at low temperatures, such as less than about 300° C., for example, about 275° C. It is contemplated that stoichiometric Si—Nₓ films with high quality electrical properties may be achieved utilizing the low temperature ALD processes described herein. Moreover, the present ALD processes do not require high temperature post annealing after Si—Nₓ film deposition.

The ALD processes described herein are advantageous because the high flux processing and utilization of an anhydrous nitrogen containing precursor (anhydrous hydrazine) during the ALD half cycle reactions prevent unwanted oxygen and carbon contamination. The silicon nitride control layer is ideal for nucleating various metal ALD precursors for gate oxide ALD or for nucleating further silicon growth with chlorosilane or silane precursors at lower temperatures (e.g. 275° C.) than possible without —N—Hₓ surface termination.

Generally, silicon nitride thin films formed according to the present disclosure are grown at low temperatures (e.g., 275° C.) with reduced lower half-cycle pulse times compared to conventional processes. In one embodiment, anhydrous hydrazine is utilized (e.g., obtained as vapor from a hydrazine organic solvent mixture), which serves to keep the Si-Nₓ surface free of unwanted oxygen contamination during film deposition. In another embodiment, Si—Nₓ ALD growth is accomplished by employing Si₂Cl₆ and hydrazine pulses with cycle lengths of about 5 seconds and about 240 seconds, respectively. In another example, the cycle time of Si₂Cl₆ is between about 1 second and about 10 seconds and the cycle time of hydrazine is between about 120 seconds and about 360 seconds.

In one embodiment, a reactor chamber is heated above 100° C. for a number of hours, e.g., 12 hours or more, sufficient to remove background H₂O and other oxidants/contaminants. It is also contemplated that heating the reactor chamber avoids unwanted ammonium-chloride-like byproduct crystal formation during Si—Nₓ ALD growth. In this embodiment, anhydrous hydrazine, which serves to keep the Si—Nₓ surface free of unwanted oxygen or water contamination, is used as a precursor during film deposition. A purge operation, which is performed between half cycle precursor pulses to remove excess unreacted precursor from the reaction chamber, may also be utilized.

In one embodiment, a method for lower temperature ALD deposition of silicon nitride on Si_{0.5}Ge_{0.5}(110) with little or no solid by-product formation is provided. A silicon nitride passivation layer on semiconductor surfaces can serve several practical uses, such as acting as a diffusion barrier or channel passivation layer prior to dielectric deposition in FinFETs or MOSFETs. When employed as a channel passivation layer, further reaction with an oxidant, such as anhydrous peroxide, can leave Si—N—OH termination, which is reactive with all metal ALD precursors thereby providing high nucleation density. Previous studies show stoichiometric ALD Si₃N₄ growth on Si(100) by hydrazine and Si₂Cl₆ at temperatures in excess of 350° C. with solid ammonium chloride by-product formation. The first half reaction of N₂H₄ leaves N—Hₓ surface termination, and the second reaction with Si₂Cl₆ adds silicon to the surface and creates a gaseous HCl by-product. An ammonium chloride by-product is usually caused by wall reactions of unreacted precursors.

Embodiments described herein avoid unwanted solid by-product formation and have been demonstrated by the examples described herein. STM/STS and XPS were utilized to characterize SiNₓ film growth on Si_{0.5}Ge_{0.5}(110) according to the embodiments described herein. A test chamber including a reactor chamber, dosing lines, and a dry pump was heated to 125° C. for 12 hours to allow for sufficient heating of all stainless steel components. Experiments conducted ran more than 100 ALD cycles with no visible evidence of powder formation on any walls. The pre-heating process prior to SiNx ALD is useful to eliminate the unwanted powder by-product formation.

At a substrate temperature of 275° C. and wall temperature of 20° C., the silicon nitride ALD process was performed on a p-type Si0.5Ge0.5(110) surface that underwent an ex-situ wet organic clean followed by a dip into a 2% HF/water solution with a toluene layer on top. The sample was pulled through toluene and loaded into a vacuum environment as quickly as possible to minimize native oxide formation. After a 315 MegaLangmuir anhydrous hydrazine dose, XPS showed N—Hx surface termination, and removal of half of the initial carbon contamination. A subsequent 21 MegaLangmuir Si₂Cl₆ dose followed by 17 cycles of 3 MegaLangmuir hydrazine and 3 MegaLangmuir Si₂Cl₆ lead to increased silicon nitride growth indicated by a large increase in XPS Si 2p and N 1s peaks, as well as a decrease in the Ge 3d substrate peak. Wall temperatures of the reactor may be heated to prevent deposition thereon and suitable wall temperatures may range from about 20° C. to about 125° C. In another embodiment, the wall temperature is greater than about 125° C.

Silicon nitride films formed according to the ALD processes described herein provide several advantages. For example, dangling bonds of the substrate are transferred to silicon, which are then passivated by nitrogen, leaving the surface electrically passivated. The silicon nitride deposited overlayer with —NHₓ termination can also react with an oxidant such as anhydrous HOOH(g) in order to create an Si—N—OH terminating layer which reacts with nearly any metal ALD precursor. Further, metal precursor nucleation (e.g. trimethyl aluminum pre-dosing) is eliminated or substantially reduced, resulting in decreasing EOT, lowering border trap density and fixed charged associated with interfacial layers, and/or direct bonding of oxide to non-silicon semiconductors.

The same process described above can be used for other crystallographic faces, such as InₓGa₁₋ₓAs(110), InₓGa₁₋ₓSb(110), InₓGa₁₋ₓN(110), SiGe(001), and SiGe(110). Advantageously, the Si—Nₓ overlayer can act as a channel diffusion barrier; for example, on InGaAs preventing In/Ga diffusion into the gate oxide or on SiGe or Ge preventing diffusion of Ge into the gate oxide. On SiGe or Ge, the Si— Nₓ overlayer can create a Ge-free interface to the gate oxide. In addition, the Si— Nₓ overlayer can also be employed for diffusion barrier applications needed during further MOS device processing steps. Moreover, the Si—Nₓ control layer can be employed directly as a gate dielectric material, as silicon nitride is an inherently wide bandgap semiconductor material. Still further, embodiments described herein are contemplated to provide improved utility in creating a silicon rich surface layer on the SiGe surfaces, which enables driving germanium down to subsurface layers.

### Experimental Results

Experiments will now be discussed to illustrate an exemplary embodiment of the disclosure. The example silicon nitride ALD process begins with a p-type Si_{0.5}Ge (110) surface undergoing an ex-situ wet organic clean with a ten minute sonication in acetone, followed by ten minute sonication in IPA, followed by ten minute sonication in water. The sample is then dipped into a beaker which contains a 2% HF/water solution with a layer of toluene on top for 2 minutes. After 2 minutes, the sample is pulled out through the layer of toluene and quickly transferred into an ultra-high vacuum (UHV, less than about 10⁻⁹ Torr) chamber before the layer of toluene evaporates from the surface. This process is done in order to prevent the sample from being air exposed following the 2% HF dip. Once the sample is in UHV, an X-ray photoelectron spectroscopy (XPS) spectrum was taken of the surface with a monochromatic aluminum channel X-ray source system at a glancing angle of 30°. Next, the sample was sequentially dosed with 315 MegaLangmuir anhydrous hydrazine, followed by 21 MegaLanmguir Si₂Cl₆, 3 MegaLangmuir anhydrous hydrazine, and 17 silicon nitride ALD cycles all dosed at a sample temperature of 275° C.

Here, each silicon nitride ALD cycle consists of 3 MegaLangmuir Si₂Cl₆ followed by 3 MegaLangmuir hydrazine at 275° C. Following each dose and the 17 silicon nitride ALD cycles, an XPS spectrum was taken of the surface to compare against the as-loaded SiGe(110) surface. The XPS raw counts corrected by Schofield photoionization cross sectional relative sensitivity factors are recorded for doublet peak pairs of Ge 3d, Si 2p, and Cl 2p and O 1s, C 1s, and N 1s peaks for the as-loaded Si_{0.5}Ge(110) surface, the 315 MegaLangmuir hydrazine dosed surface, the additional 21 MegaLangmuir Si₂Cl₆ dosed surface, and the additional 17 silicon nitride ALD cycle dosed surface. All doses were done at a substrate temperature of 275° C.

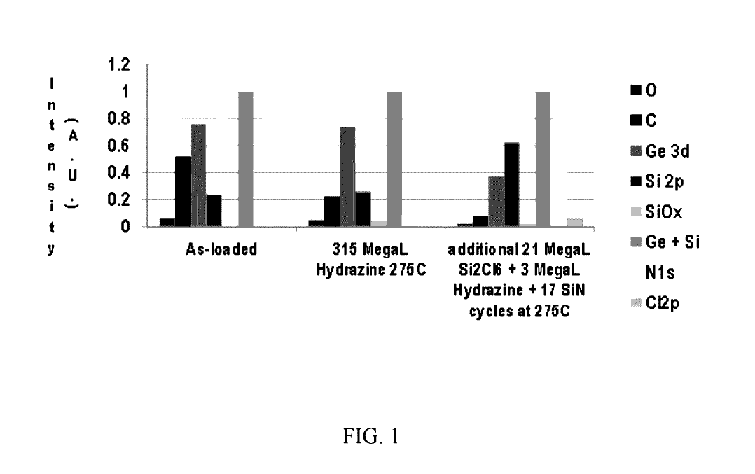

FIG. 1 illustrates the XPS corrected raw counts for the above process. More specifically, FIG. 1 illustrates monochromatic aluminum channel X-ray flood source system raw counts corrected by Schofield photoionization cross sectional relative sensitivity factors for wet cleaned as-loaded Si_{0.5}Ge (110) surface, Si_{0.5}Ge(110) surface following 315 MegaLangmuir hydrazine at 275° C., and Si_{0.5}Ge (110) surface following 315 MegaLangmuir hydrazine plus 21 MegaLanmguir Si₂Cl₆ plus 17 silicon nitride ALD cycles, all dosed at 275° C. The As-loaded SiGe(110) surface contains a large amount (50%) of carbon contamination and a small amount (<10%) of oxygen contamination. This is due to the ex-situ wet cleaning procedure not fully etching unwanted surface contamination or protecting the etched surface from contamination during the sample transfer into vacuum.

An in-situ surface cleaning technique such as the SiCoNi process and atomic hydrogen cleaning could leave the SiGe(110) surface free of oxygen and carbon contamination. The SiCoNi process is available from Applied Materials, Inc., Santa Clara, Calif. The initial 315 MegaLangmuir hydrazine dose is able to remove more than half of the carbon contamination from the surface and also creates the —N—Hₓ surface termination as seen by the presence of the N 1s signal. Next, by dosing 21 MegaLangmuir Si₂Cl₆ followed by 3 MegaLangmuir hydrazine, and the 17 silicon nitride cycles, a large increase in the Si 2p and N 1s corrected peak areas is seen, as well as a decrease in the Ge 3d substrate peak, and the C 1s and O 1s surface contamination peaks. These results are consistent with silicon nitride ALD deposition occurring with no indication of unwanted contaminants being deposited within the silicon nitride film.

It was found that the ALD process produces an unwanted ammonium-chloride like powder byproduct when the reaction chamber and precursor lines are at 25° C. and a turbo molecular pump is employed to pump out gaseous byproducts and unreacted precursors from the reaction chamber. This was discovered by visibly seeing white powder in the ALD reaction chamber and on the surface of the sample following the 17 silicon nitride ALD cycles. The XPS results following the 17 silicon nitride cycles also shows a residual chlorine signal which can be attributed to the white powder left on the sample surface following the ALD process.

Also, at room temperature hydrazine and Si₂Cl₆ may stick to the chamber walls and react to form the unwanted powder byproduct, so testing was employed to determine the chamber temperature and pumping set-up to avoid the unwanted formation of the powder byproduct.

The test apparatus included the ALD chamber with attached precursor dosing lines being connected to a dry pump, and the entire chamber, precursor dosing lines, and connecting line to the dry pump all heated for 12 hours to 125° C. 12 hours of heating time was employed to ensure all stainless steel vacuum components reach the temperature of >100° C., to ensure both precursors will not stick to the chamber walls and to eliminate the formation of the ammonium-chloride like powder byproduct. In operation, several silicon nitride ALD cycles were introduced into the chamber (>100 cycles where each cycle consists of 3 MegaLangmuir hydrazine followed by 3 MegaLangmuir Si₂Cl₆) and no powder detected in the ALD chamber, precursor dosing lines, or line connecting to the dry pump. Thus, chamber conditioning is utilized to eliminate the unwanted formation of the powder byproduct by ensuring all stainless steel is above 100° C. prior to dosing. The silicon nitride process was tested on Si_{0.5}Ge (110), but results also support formation on SiGe(001), and crystallographic faces of III-V substrates.

### Applications

The ALD deposited silicon nitride control layer formed according to the embodiments described herein may be applicable for use as a semiconductor functionalization protection layer while providing protection in vacuum from oxidation and carburization. This application will serve useful during deposition and processing of gate stacks on FinFETs. This application is contemplated to be especially useful for high performance logic devices fabrication processes. As described above, embodiments provided herein enable Si—Nₓ termination which chemically protects the semiconductor substrate.

Embodiments described herein can also be applied, for example, for planar MOSFETs or gate-all-around (GAA) FET gate dielectric fabrication processes. In addition, Si—Nₓ termination is contemplated to be useful for MOSFETs, FINFETs and GAAFETs source and drain (S/D) contact interface fabrication processes. Embodiments described herein are also contemplated to be advantageously employed in metal-insulator-semiconductor (MIS) integration schemes. MIS contacts may be applied instead of silicide contacts for Rc scaling and the embodiments described herein are contemplated to assist formation of ultrathin tunneling metal oxide materials.

While the foregoing is directed to embodiments of the present disclosure, other and further embodiments of the disclosure may be devised without departing from the basic scope thereof, and the scope thereof is determined by the claims that follow.

What is claimed is:

1. An atomic layer deposition method, comprising:
heating a substrate in a reaction chamber to a temperature less than about 300° C.,
introducing a first precursor pulse comprising N₂H₄ into the reaction chamber; and
introducing a second precursor pulse comprising Si₂Cl₆ into the reaction chamber, wherein the first precursor pulse and the second precursor pulse are performed at the temperature less than about 300° C.

2. The method of claim 1, wherein the temperature is about 275° C.

3. The method of claim 1, wherein the substrate comprises one or more of indium gallium arsenide, indium gallium antimonide, indium gallium nitride, silicon germanium, germanium, silicon, and metallic materials.

4. The method of claim 3, wherein the substrate comprises Si_{0.5}Ge_{0.5}.

5. The method of claim 4, wherein the Si_{0.5}Ge_{0.5} substrate has a (110) crystal lattice structure.

6. The method of claim 1, wherein the first precursor pulse is a 315 MegaLangmuir N₂H₄ dose.

7. The method of claim 1, wherein the second precursor pulse is a 21 MegaLangmuir Si₂Cl₆ dose.

8. The method of claim 1, further comprising:
repeating the introducing a first precursor pulse comprising N₂H₄ and the introducing a second precursor pulse comprising Si₂Cl₆.

9. The method of claim 8, wherein the repeating is performed sequentially.

10. The method of claim 9, wherein the sequential repeating is performed 17 times.

11. The method of claim 8, wherein the repeating the introducing a first precursor pulse comprising N₂H₄ is performed with a 3 MegaLangmuir N₂H₄ dose.

12. The method of claim 11, wherein the repeating the introducing a second precursor pulse comprising Si₂Cl₆ is performed with a 3 MegaLangmuir Si₂Cl₆ dose.

13. The method of claim 1, further comprising:
heating the reaction chamber and dosing delivery lines to a temperature that prevents reaction of the precursors within the reaction chamber and dosing lines.

14. The method of claim 13, wherein the heating elevates a temperature of the reaction chamber and the dosing delivery lines to at least 125° C.

15. An atomic layer deposition method, comprising:
heating a substrate in a reaction chamber to a temperature of about 275° C.;
introducing a first precursor pulse comprising N₂H₄ at a first dosage into the reaction chamber; and
introducing a second precursor pulse comprising Si₂Cl₆ at a second dosage less than the first dosage into the reaction chamber, wherein the first precursor pulse and the second precursor pulse are performed at the temperature less than about 275° C.

16. The method of claim 15, wherein the substrate comprises one or more of indium gallium arsenide, indium gallium antimonide, indium gallium nitride, silicon germanium, germanium, silicon, and metallic materials.

17. The method of claim 15, further comprising:
sequentially repeating the introducing a first precursor pulse comprising N₂H₄ and the introducing a second precursor pulse comprising Si₂Cl₆.

18. The method of claim 17, wherein the repeating the introducing a first precursor pulse comprising N₂H₄ is performed at a third dosage and the repeating the introducing a second precursor pulse comprising Si₂Cl₆ is performed at a fourth dosage.

19. The method of claim 18, wherein the third dosage and the fourth dosage are the same and less than both of the first dosage and the second dosage.

20. An atomic layer deposition method, comprising:
heating a substrate in a reaction chamber to a temperature less than about 300° C.,
introducing a first precursor pulse comprising N₂H₄ at a first dosage of 315 MegaLangmuir into the reaction chamber;
introducing a second precursor pulse comprising Si₂Cl₆ at a second dosage of 21 MegaLangmuir into the reaction chamber;
introducing a third precursor pulse comprising N₂H₄ at a third dosage of 3 MegaLangmuir into the reaction chamber;
introducing a fourth precursor pulse comprising Si₂Cl₆ at a fourth dosage of 3 MegaLangmuir into the reaction chamber; and
sequentially repeating the introducing a third precursor pulse and the introducing a fourth precursor pulse.
